(19) United States
(12) Patent Application Publication
(10) Pub. No.: US 2025/0185272 A1
(43) Pub. Date: Jun. 5, 2025

(54) SEMICONDUCTOR STRUCTURE OF HIGH ELECTRON MOBILITY TRANSISTOR

(71) Applicant: HiPer Semiconductor Inc., Taipei City (TW)

(72) Inventors: WEI-CHEN YANG, Hsinchu County (TW); WEI-CHIH HO, Hsinchu County (TW)

(73) Assignee: HiPer Semiconductor Inc., Taipei City (TW)

(21) Appl. No.: 18/937,042

(22) Filed: Nov. 5, 2024

(30) Foreign Application Priority Data
Dec. 1, 2023 (TW) 112146818

(51) Int. Cl. H01L 29/778; H01L 29/20; H01L 29/423; H01L 29/66

(52) U.S. Cl. CPC H10D 30/475; H10D 30/015; H10D 62/8503; H10D 64/513

(57) ABSTRACT

A semiconductor structure of a high electron mobility transistor includes a channel layer, a barrier layer, a gate, a n-type material structure, and a metal electrode. The barrier layer is formed on the channel layer. A two-dimensional electron gas is formed in the channel layer along an interface between the channel layer and the barrier layer. The gate is formed on the barrier layer. The n-type material structure is in contact with the barrier layer. The metal electrode is a drain or a source and is disposed on a side of the gate.

### BACKGROUND OF THE INVENTION

### Technical Field

The present invention relates generally to a high electron mobility transistor, and more particularly to a high electron mobility transistor having a n-type material structure.

### Description of Related Art

A high electron mobility transistor (HEMT) is typically a structure having a heterojunction formed on a substrate, wherein a two-dimensional electron gas (2DEG) is formed on the heterojunction between two materials with different energy gaps. As the HEMT makes use of the 2DEG having a high electron mobility as a carrier channel of the transistor, the HEMT has features of a high breakdown voltage, the high electron mobility, a low on-resistance, and a low input capacitance, thereby the HEMT could be widely applied to high power semiconductor devices.

A low breakdown voltage, a high electric field, and an on-resistance are three main problems of the high electron mobility transistor. Conventionally, a drain field plate is provided to resolve the aforementioned technical problems. However, the improvement of the high electric field at the drain by providing the drain field plate is limited, and the size of the integrated circuit could not be effectively reduced by the conventional way. Therefore, how to provide a high electron mobility transistor which could increase a breakdown voltage and decrease an electric field and an on-resistance deterioration speed, is a problem needed to be solved in the industry.

### BRIEF SUMMARY OF THE INVENTION

In view of the above, the primary objective of the present invention is to provide a semiconductor structure of a high electron mobility transistor, which could increase a breakdown voltage and decrease an electric field and an on-resistance deterioration speed.

The present invention provides a semiconductor structure of a high electron mobility transistor, including a channel layer, a barrier layer, a gate, a n-type material structure, and a metal electrode. The barrier layer is formed on the channel layer. In the channel layer, a two-dimensional electron gas is formed in the channel layer along an interface between the channel layer and the barrier layer. The gate is formed on the barrier layer. The n-type material structure is in contact with the barrier layer. The metal electrode is a drain or a source and is disposed on a side of the gate.

In an embodiment, a part of the n-type material structure is in contact with the metal electrode.

In an embodiment, at least a part of the metal electrode is disposed on the n-type material structure.

In an embodiment, at least a part of the n-type material structure is disposed on the barrier layer; the n-type material structure has a first exposed portion, wherein the first exposed portion is not covered by the metal electrode.

In an embodiment, the first exposed portion has a first width and a second width; the first width is unequal to the second width.

In an embodiment, a side of the n-type material structure facing the gate further has a second exposed portion; the second exposed portion is located on the first exposed portion and is not covered by the metal electrode.

In an embodiment, the semiconductor structure includes a trench, wherein at least a part of the n-type material structure is disposed in the trench.

In an embodiment, the part of the n-type material structure disposed in the trench forms a stepped recess; the metal electrode is disposed on the stepped recess and partially covers the n-type material structure.

In an embodiment, the n-type material structure and the metal electrode are formed on the barrier layer; a bottom of the n-type material structure is in contact with the barrier layer or the channel layer; the metal electrode is partially disposed on the n-type material structure and at least covers a side wall of the n-type material structure.

In an embodiment, the semiconductor structure includes at least one floating structure disposed between the gate and the metal electrode, wherein the at least one floating structure is formed by a n-type material.

In an embodiment, the semiconductor structure includes a protective layer, wherein the metal electrode has an extending portion; the protective layer is disposed between the extending portion and the n-type material structure; a projection of the extending portion at least partially covers the n-type material structure in a vertical direction.

In an embodiment, a horizontal reference axis is defined; a side of the gate facing the n-type material structure has a first side; a side of the n-type material structure facing the gate has a second side; a distance between the first side and the second side is a first distance; in the horizontal reference axis, a side of the metal electrode facing the gate and partially covering the n-type material structure has a length, wherein the length is greater than or equal to 0.1 um and is less than or equal to ½ of the first distance.

In an embodiment, the semiconductor structure includes at least one floating structure, wherein the n-type material structure and the at least one floating structure are disposed between the gate and the metal electrode.

In an embodiment, a thickness between a surface of the n-type material structure away from the barrier layer and a surface of the n-type material structure being in contact with the barrier layer is greater than or equal to 5 nm.

In an embodiment, a horizontal reference axis is defined; a side of the gate facing the n-type material structure has a first side; a side of the n-type material structure facing the gate has a second side; a side of the metal electrode facing the gate has a fourth side; in the horizontal reference axis, a distance between the first side and the second side is a first distance and a maximum distance between the first side and the fourth side is a second distance, wherein the first distance is less than the second distance.

In an embodiment, in the horizontal reference axis, a third distance between a position of the second side, which is the closest to the gate, and the fourth side is greater than or equal to 0.1 um and is less than or equal to ½ of the second distance.

With the aforementioned design, the present invention could increase a breakdown voltage and decrease an electric field and an on-resistance deterioration speed by the n-type structure being in contact with the barrier layer.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic sectional view of the semiconductor structure of the high electron mobility transistor according to a first embodiment of the present invention;

FIG. 2 is a schematic view showing a relationship between the drain current and the drain voltage of the high electron mobility transistor of the first embodiment and the high electron mobility transistor of a comparative example;

FIG. 3 is a schematic view showing a relationship between the drain current and the gate voltage of the high electron mobility transistor and the high electron mobility transistor of the comparative example;

FIG. 4 is a schematic sectional view of the semiconductor structure of the high electron mobility transistor according to another embodiment of the present invention;

FIG. 5 is a schematic sectional view of the semiconductor structure of the high electron mobility transistor according to a second embodiment of the present invention;

FIG. 6 is a schematic sectional view of the semiconductor structure of the high electron mobility transistor according to a third embodiment of the present invention;

FIG. 7 is a schematic sectional view of the semiconductor structure of the high electron mobility transistor according to another embodiment of the present invention;

FIG. 8 is a schematic sectional view of the semiconductor structure of the high electron mobility transistor according to a fourth embodiment of the present invention;

FIG. 9 is a schematic sectional view of the semiconductor structure of the high electron mobility transistor according to another embodiment of the present invention;

FIG. 10 is a schematic sectional view of the semiconductor structure of the high electron mobility transistor according to a fifth embodiment of the present invention;

FIG. 11 is a schematic sectional view of the semiconductor structure of the high electron mobility transistor according to another embodiment of the present invention; and

FIG. 12 is a schematic sectional view of the semiconductor structure of the high electron mobility transistor according to a sixth embodiment of the present invention.

### DETAILED DESCRIPTION OF THE INVENTION

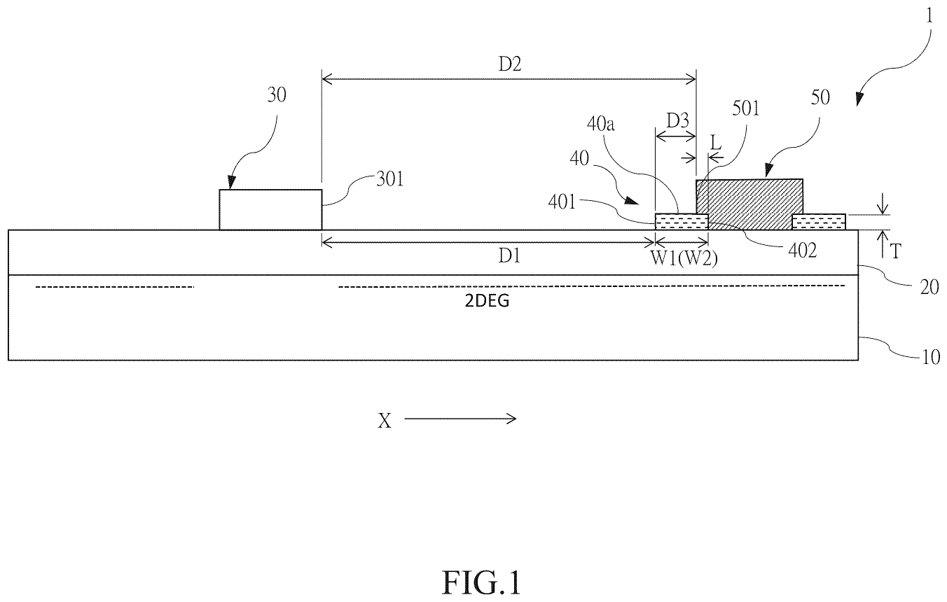

A semiconductor structure 1 of a high electron mobility transistor according to a first embodiment of the present invention is illustrated in FIG. 1 and includes a channel layer 10, a barrier layer 20, a gate 30, a n-type material structure 40, and a metal electrode 50. The barrier layer 20 is formed on the channel layer 10. In the channel layer 10, a two-dimensional electron gas (2DEG) is formed along an interface between the channel layer 10 and the barrier layer 20. The gate 30 is formed on the barrier layer 20. The n-type material structure 40 is in contact with the barrier layer 20. The metal electrode 50 is a drain or a source and is disposed on a side of the gate 30. In the current embodiment, the metal electrode 50 is a drain as an example for illustration. In this way, by providing the n-type material structure 40 to be in contact with the barrier layer 20, a breakdown voltage could be increased and an electric field and an on-resistance deterioration speed could be decreased.

The channel layer 10 could be a gallium nitride (GaN) channel layer. The barrier layer 20 could be an aluminum-gallium nitride (AlGaN) barrier layer. The n-type material structure 40 could be formed by a nitride, such as GaN, AlN, InN, AlGaN, InGaN, InAlGaN, etc., doped with a n-type dopant through doping, diffusion, or ion implantation. The n-type material structure 40 could be a single-layer nitride stacked layer or a structure including a plurality of nitride stacked layers. The metal electrode 50 could be, for example, a titanium electrode or an aluminum electrode. In the current embodiment, the gate 30 could be a gallium nitride gate with a p-type dopant (pGaN). In other embodiments, the gate 30 could also be a gallium nitride gate with a n-type dopant (nGaN) or a metallic structure. The high electron mobility transistor according to the first embodiment of the present invention is an enhancement mode gallium nitride (E-Mode GaN) transistor. In other embodiments, the high electron mobility transistor could also be a depletion mode gallium nitride (D-Mode GaN) transistor.

As shown in FIG. 1, the n-type material structure 40 and the metal electrode 50 are formed on the barrier layer 20, wherein a part of the n-type material structure 40 is in contact with the metal electrode 50. At least a part of the metal electrode 50 is disposed on the n-type material structure 40. The n-type material structure 40 has a first exposed portion 40a, wherein the first exposed portion 40a is a part of the n-type material structure 40 that is not covered by the metal electrode 50. A bottom of the n-type material structure 40 and a bottom of the metal electrode 50 are in contact with the barrier layer 20. The metal electrode 50 at least covers a side wall of the n-type material structure 40. A horizontal reference axis X is defined. In the horizontal reference axis X, a side of the gate 30 facing the n-type material structure 40 has a first side 301; a side of the n-type material structure 40 facing the gate 30 has a second side 401; a side of the n-type material structure 40 away from the gate 30 has a third side 402. The metal electrode 50 covers the third side 402 of the n-type material structure 40. In the horizontal reference axis X, a side of the metal electrode 50 facing the gate 30 has a fourth side 501. In the horizontal reference axis X, a distance between the first side 301 and the second side 401 is a first distance D1; a distance between the first side 301 and the fourth side 501 is a second distance D2; the first distance D1 is less than the second distance D2. In the horizontal reference axis X, a third distance D3 between the second side 401 and the fourth side 501 is greater than or equal to 0.1 um and is less than or equal to ½ of the second distance D2. In the horizontal reference axis X, a side of the metal electrode 50, which faces the gate 30 and partially covers the n-type material structure 40 has a length L, wherein the length L is greater than or equal to 0.1 um and is less than or equal to ½ of the first distance D1. A thickness T of the n-type material structure 40 between a surface of the n-type material structure 40 away from the barrier layer 20 and a surface of the n-type material structure 40 being in contact with the barrier layer 20 is greater than or equal to 5 nm.

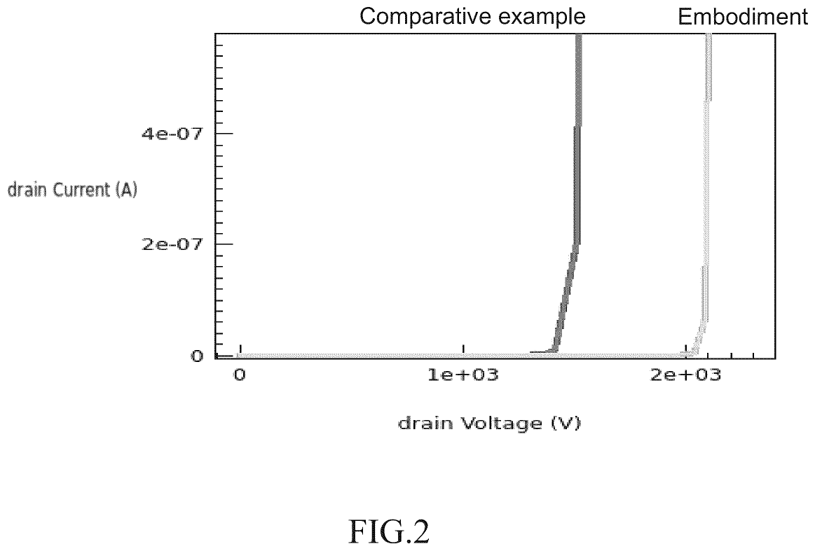

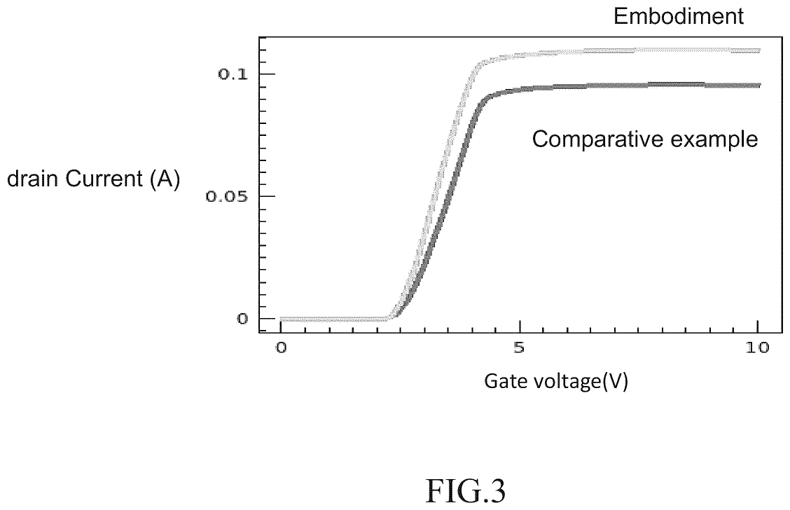

FIG. 2 is a schematic view showing a relationship between a drain current and a drain voltage of the high electron mobility transistor of the first embodiment and a high electron mobility transistor of a comparative example and FIG. 3 is a schematic view showing a relationship between the drain current and a gate voltage of the high electron mobility transistor and the high electron mobility transistor of the comparative example. The structural difference between the high electron mobility transistor of the comparative example and the high electron mobility transistor of the first embodiment is that the high electron mobility transistor of the comparative example does not have the n-type material structure 40, and a metal electrode that is a drain is directly stacked on a barrier layer. It can be seen from FIG. 2 and FIG. 3 that in comparison with the comparative example, the first embodiment could effectively increase a breakdown voltage and the drain current of the high electron mobility transistor by the n-type material structure 40 being in contact with the barrier layer 20.

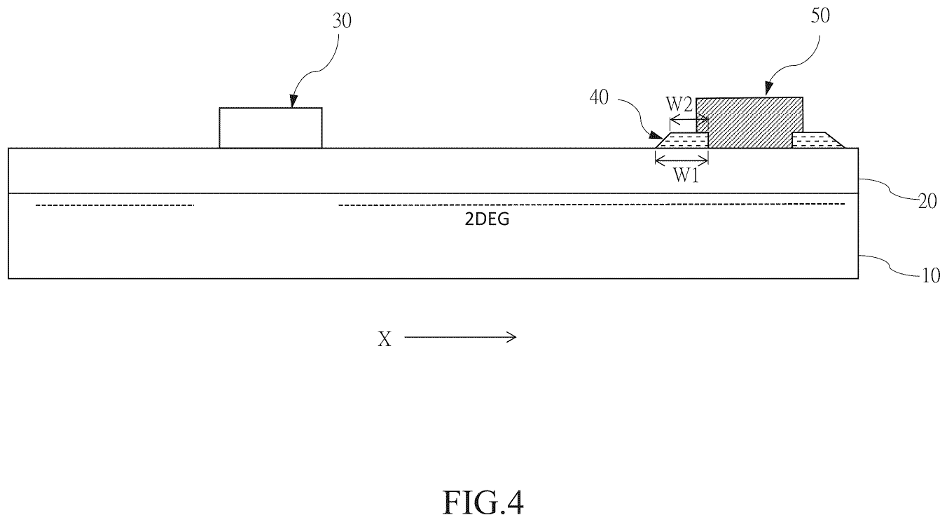

As shown in FIG. 1, the first exposed portion 40a of the n-type material structure 40 has a first width W1 and a second width W2. The first width W1 is a width of a side of the first exposed portion 40a being in contact with a surface of the barrier layer 20 in the horizontal reference axis X. The second width W2 is a width of a side of the first exposed portion 40a away from the surface of the barrier layer 20 in the horizontal reference axis X. In the current embodiment, the first width W1 is substantially equal to the second width W2 as an example for illustration. Referring to FIG. 4, in other embodiments, the first width W1 could be unequal to the second width W2; for example, the first width W1 is greater than the second width W2.

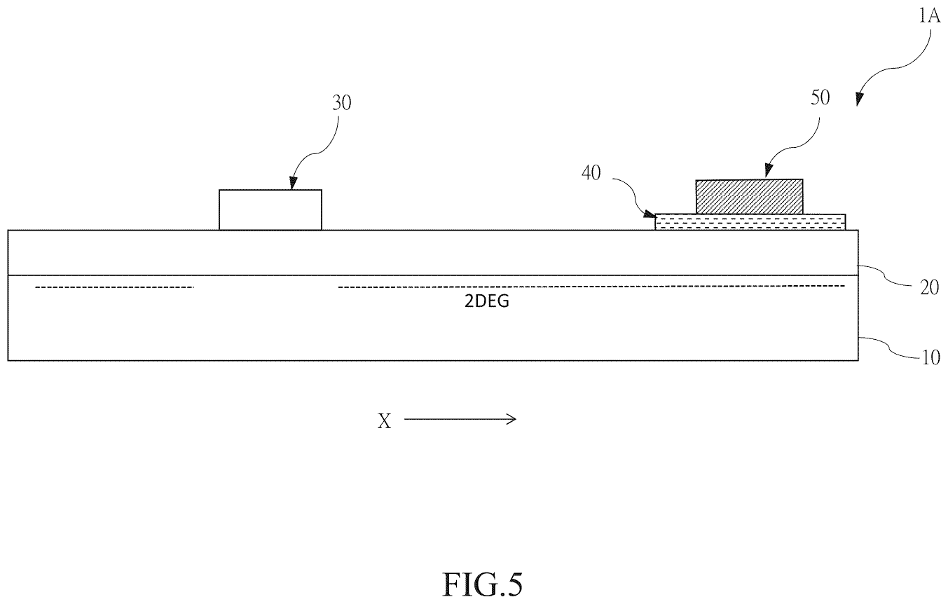

A semiconductor structure 1A of a high electron mobility transistor according to a second embodiment of the present invention is illustrated in FIG. 5 and has almost the same structure as that of the semiconductor structure 1 of the high electron mobility transistor of the first embodiment, except that the bottom of the metal electrode 50 of the second embodiment could be in contact with a top of the n-type material structure 40 as shown in FIG. 5.

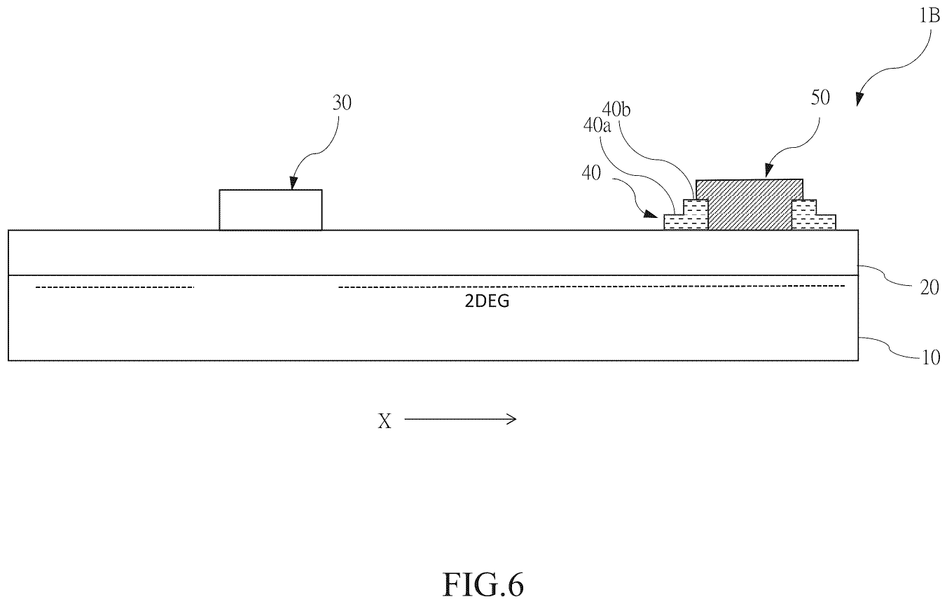

A semiconductor structure 1B of a high electron mobility transistor according to a third embodiment is illustrated in FIG. 6 and has almost the same structure as that of the semiconductor structure 1 of the high electron mobility transistor of the first embodiment, except that the side of the n-type material structure 40 facing the gate 30 of the first embodiment has the first exposed portion 40a as an example for illustration, but the side of the n-type material structure 40 facing the gate 30 of the third embodiment further has a second exposed portion 40b. The second exposed portion 40b is located on the first exposed portion 40a and is stacked on the first exposed portion 40a. The second exposed portion 40b is not covered by the metal electrode 50.

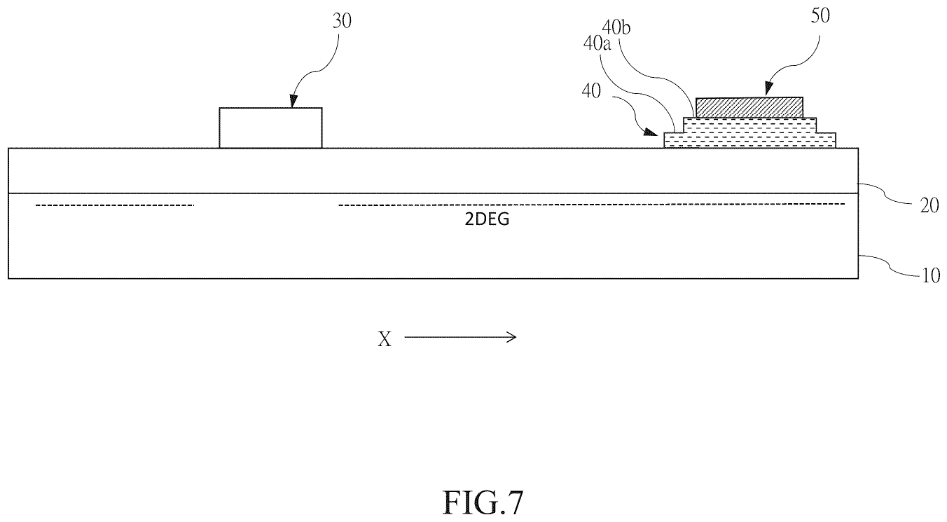

Moreover, in the current embodiment, the bottom of the metal electrode 50 is in contact with the barrier layer 20 as an example for illustration. In other embodiment, the bottom of the metal electrode 50 could be in contact with the top of the n-type material structure 40 and is not in contact with the barrier layer 20 as shown in FIG. 7.

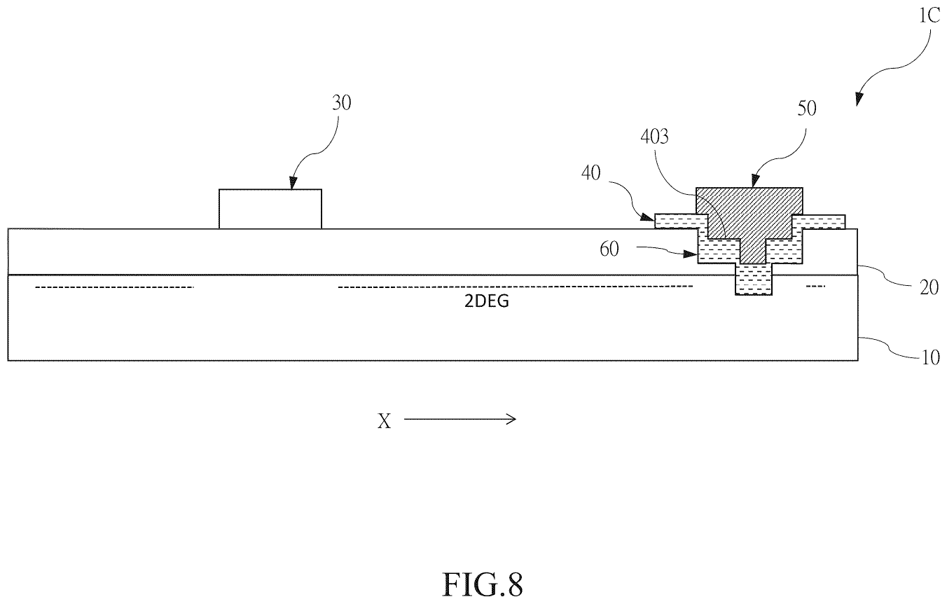

A semiconductor structure 1C of a high electron mobility transistor according to a fourth embodiment of the present invention is illustrated in FIG. 8 and has almost the same structure as that of the semiconductor structure 1 of the high electron mobility transistor of the first embodiment, except that the bottom of the n-type material structure 40 of the first embodiment is in contact with the barrier layer 20 as an example for illustration, but the bottom of the n-type material structure 40 of the fourth embodiment could be in contact with the barrier layer 20 and the channel layer 10 as shown in FIG. 8. At least a part of the n-type material structure 40 of the fourth embodiment is disposed on the barrier layer 20.

Additionally, in the current embodiment, the semiconductor structure 1C of the high electron mobility transistor further includes a trench 60. At least a part of the n-type material structure 40 is disposed in the trench 60. A top of the n-type material structure 40, which is disposed in the trench 60, forms a recess 403 that is in a stepped shape. The metal electrode 50 is disposed on the stepped recess 403 and partially covers a part of the n-type material structure 40. Another part of the n-type material structure 40 is not covered by the metal electrode 50. In the current embodiment, the trench 60 is a stepped trench. In other embodiments, the trench 60 could be a trench in any shape. In the current embodiment, the recess 403 is a stepped recess. In other embodiments, the recess 403 could be a recess in any shape.

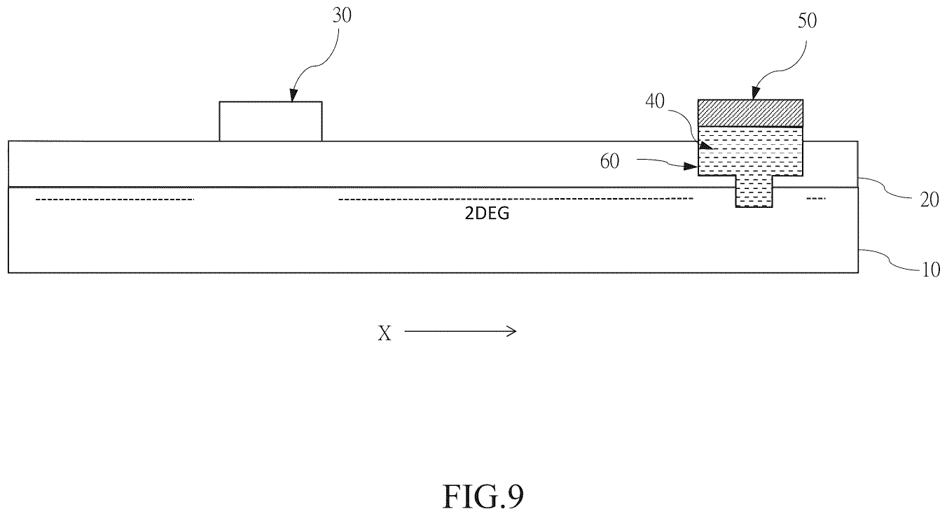

Moreover, in the current embodiment, at least a part of the n-type material structure 40 is disposed in the trench 60 and the metal electrode 50 is disposed on the stepped recess 403 of the n-type material structure 40 and covers a part of the n-type material structure 40 as an example for illustration. In other embodiments, the n-type material structure 40 could completely disposed in the trench 60 and the metal electrode 50 is disposed on the top of the n-type material structure 40 and completely covers the top of the n-type material structure 40 as shown in FIG. 9.

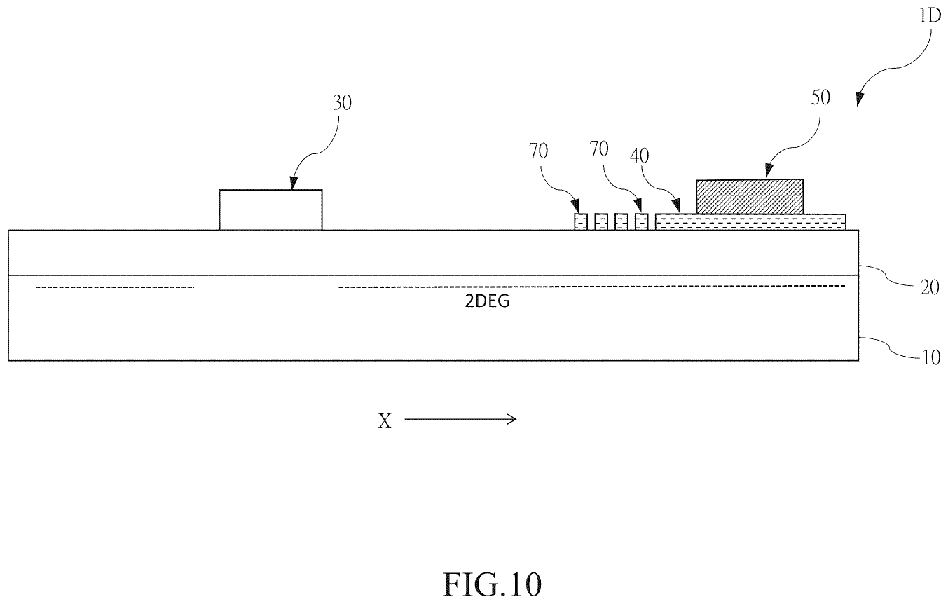

A semiconductor structure 1D of a high electron mobility transistor according to a fifth embodiment of the present invention is illustrated in FIG. 10 and has almost the same structure as that of the semiconductor structure 1A of the high electron mobility transistor of the second embodiment, except that the semiconductor structure 1D of the high electron mobility transistor of the fifth embodiment further includes a plurality of floating structures 70 arranged between the gate 30 and the metal electrode 50 along the horizontal reference axis X. In this way, the floating structures 70 could increase a carrier concentration of the two-dimensional electron gas (2DEG) and disperse an electric field of the metal electrode 50, which is a drain.

The floating structures 70 are made of a n-type material. The n-type material could be formed by a nitride, such as GaN, AlN, InN, AlGaN, InGaN, InAlGaN, etc., doped with a n-type dopant through doping, diffusion, or ion implantation. In the current embodiment, the floating structures 70 and the n-type material structure 40 are formed by the same n-type material and are formed by the same process at the same time. In other embodiments, the floating structures 70 and the n-type material structure 40 could be formed by different n-type materials and could be formed by different processes. Moreover, in other embodiments, the number of the floating structure 70 could be one or plural, which could also achieve the effect of increasing the carrier concentration of the two-dimensional electron gas (2DEG) and dispersing the electric field of the metal electrode 50 that is a drain.

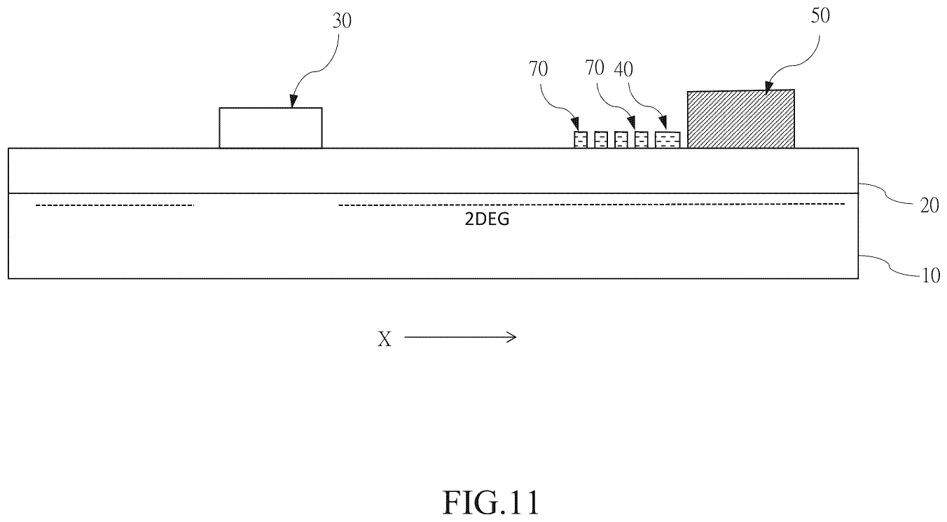

In addition, in the current embodiment, the n-type material structure 40 is in contact with the metal electrode 50 as an example for illustration. In other embodiments, the n-type material structure 40 could be not in contact with the metal electrode 50 as shown in FIG. 11, wherein the n-type material structure 40 and the floating structures 70 are arranged between the gate 30 and the metal electrode 50 along the horizontal reference axis X, and the n-type material structure 40 is disposed at a position closer to the metal electrode 50, which is a drain, than the floating structures 70.

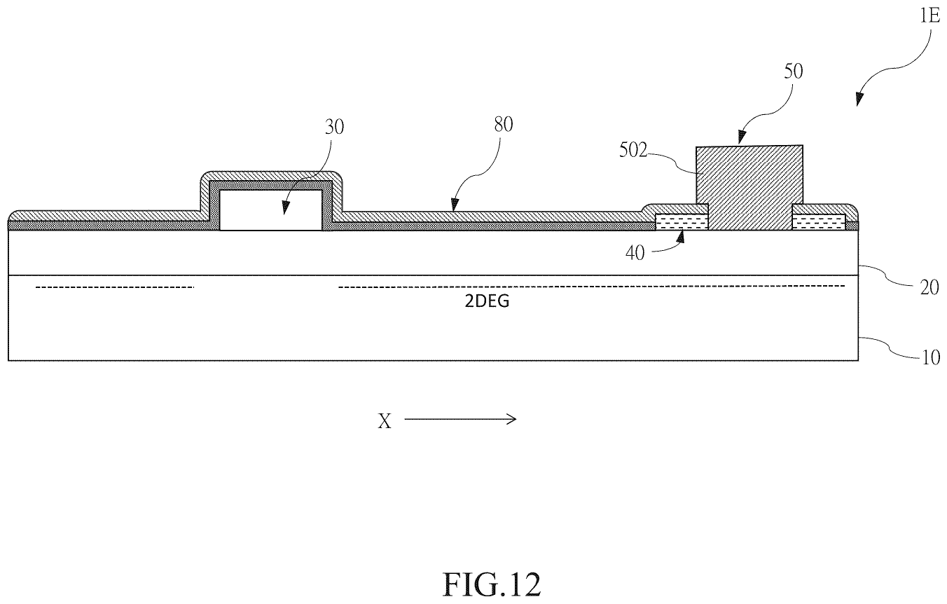

A semiconductor structure 1E of a high electron mobility transistor according to a sixth embodiment of the present invention is illustrated in FIG. 12 and has almost the same structure as that of the semiconductor structure 1 of the high electron mobility transistor of the first embodiment, except that the semiconductor structure 1E of the high electron mobility transistor of the sixth embodiment further includes a protective layer 80 and the metal electrode 50 has an extending portion 502 extending in a direction toward the gate 30 along the horizontal reference axis X. The protective layer 80 is disposed between the extending portion 502 and the n-type material structure 40. A projection of the extending portion 502 at least partially covers the n-type material structure 40 in a vertical direction. The protective layer 80 could be, for example, a silicon dioxide protective layer.

With the aforementioned design, the present invention could effectively increase a breakdown voltage and decrease an electric field and an on-resistance deterioration speed by the n-type material structure 40 being in contact with the barrier layer 20.

It must be pointed out that the embodiments described above are only some preferred embodiments of the present invention. All equivalent structures and methods which employ the concepts disclosed in this specification and the appended claims should fall within the scope of the present invention.

What is claimed is:

1. A semiconductor structure of a high electron mobility transistor, comprising:
a channel layer;
a barrier layer formed on the channel layer, wherein in the channel layer, a two-dimensional electron gas is formed along an interface between the channel layer and the barrier layer;
a gate formed on the barrier layer;
a n-type material structure being in contact with the barrier layer; and
a metal electrode, which is a drain or a source, wherein the metal electrode is disposed on a side of the gate;
wherein a part of the n-type material structure is in contact with the metal electrode; at least a part of the metal electrode is disposed on the n-type material structure; at least a part of the n-type material structure is disposed on the barrier layer; the n-type material structure has a first exposed portion, wherein the first exposed portion is not covered by the metal electrode.

2. The semiconductor structure as claimed in claim 1, wherein the first exposed portion has a first width and a second width; the first width is unequal to the second width.

3. The semiconductor structure as claimed in claim 1, wherein a side of the n-type material structure facing the gate further has a second exposed portion; the second exposed portion is located on the first exposed portion and is not covered by the metal electrode.

4. A semiconductor structure of a high electron mobility transistor, comprising:
a channel layer;
a barrier layer formed on the channel layer, wherein in the channel layer, a two-dimensional electron gas is formed along an interface between the channel layer and the barrier layer;
a gate formed on the barrier layer;
a n-type material structure being in contact with the barrier layer;
a metal electrode, which is a drain or a source, wherein the metal electrode is disposed on a side of the gate; and
a trench, wherein at least a part of the n-type material structure is disposed in the trench;
wherein a part of the n-type material structure is in contact with the metal electrode; at least a part of the metal electrode is disposed on the n-type material structure.

5. The semiconductor structure as claimed in claim 4, wherein the part of the n-type material structure disposed in the trench forms a stepped recess; the metal electrode is disposed on the stepped recess and partially covers the n-type material structure.

6. The semiconductor structure as claimed in claim 1, wherein the n-type material structure and the metal electrode are formed on the barrier layer; a bottom of the n-type material structure is in contact with the barrier layer or the channel layer; the metal electrode is partially disposed on the n-type material structure and at least covers a side wall of the n-type material structure.

7. The semiconductor structure as claimed in claim 1, further comprising at least one floating structure disposed between the gate and the metal electrode, wherein the at least one floating structure is formed by a n-type material.

8. The semiconductor structure as claimed in claim 1, further comprising a protective layer, wherein the metal electrode has an extending portion; the protective layer is disposed between the extending portion and the n-type material structure; a projection of the extending portion at least partially covers the n-type material structure in a vertical direction.

9. The semiconductor structure as claimed in claim 1, wherein a horizontal reference axis is defined; a side of the gate facing the n-type material structure has a first side; a side of the n-type material structure facing the gate has a second side; a distance between the first side and the second side is a first distance; in the horizontal reference axis, a side of the metal electrode facing the gate and partially covering the n-type material structure has a length, wherein the length is greater than or equal to 0.1 um and is less than or equal to ½ of the first distance.

10. A semiconductor structure of a high electron mobility transistor, comprising:
a channel layer;
a barrier layer formed on the channel layer, wherein in the channel layer, a two-dimensional electron gas is formed along an interface between the channel layer and the barrier layer;
a gate formed on the barrier layer;
a n-type material structure being in contact with the barrier layer;
a metal electrode, which is a drain or a source, wherein the metal electrode is disposed on a side of the gate; and
at least one floating structure, wherein the n-type material structure and the at least one floating structure are disposed between the gate and the metal electrode.

11. The semiconductor structure as claimed in claim 1, wherein a thickness between a surface of the n-type material structure away from the barrier layer and a surface of the n-type material structure being in contact with the barrier layer is greater than or equal to 5 nm.

12. The semiconductor structure as claimed in claim 1, wherein a horizontal reference axis is defined; a side of the gate facing the n-type material structure has a first side; a side of the n-type material structure facing the gate has a second side; a side of the metal electrode facing the gate has a fourth side; in the horizontal reference axis, a distance between the first side and the second side is a first distance and a maximum distance between the first side and the fourth side is a second distance, wherein the first distance is less than the second distance.

13. The semiconductor structure as claimed in claim 12, wherein in the horizontal reference axis, a third distance between a position of the second side, which is the closest to the gate, and the fourth side is greater than or equal to 0.1 um and is less than or equal to ½ of the second distance.
